(19) United States
(12) Patent Application Publication
(10) Pub. No.: US 2023/0217836 A1
(43) Pub. Date: Jul. 6, 2023

(54) MEMORY METAL HARDMASK STRUCTURE

(71) Applicant: International Business Machines Corporation, Armonk, NY (US)

(72) Inventors: Ashim Dutta, Clifton Park, NY (US); Chih-Chao Yang, Glenmont, NY (US); Hao Tang, Slingerlands, NY (US); Theodoros E Standaert, Clifton Park, NY (US)

(21) Appl. No.: 17/566,812

(22) Filed: Dec. 31, 2021

(51) Int. Cl. H01L 43/08; H01L 27/22; H01L 43/02; H01L 43/12

(52) U.S. Cl. CPC H01L 43/08; H01L 27/222; H01L 43/02; H01L 43/12

(57) ABSTRACT

A metallic hardmask is formed having a selected stress designed to create a selected amount of positive wafer bow. In preferred embodiments, metallic hardmask is disposed on a memory pillar layer over a wafer substrate. A set of memory pillars using the metal hardmask. Because of the positive wafer bow, the patterned set of memory pillars at both the edges and the central portion of the wafer substrate are aligned with a respective contact for a memory device. A positive wafer bow is defined as a bowed wafer substrate where a central portion of a patterned side of the wafer substrate is lower than edges of the wafer substrate.

### BACKGROUND OF THE INVENTION

This disclosure relates to integrated circuit devices, and more specifically, to a method and structure to improve the properties of hardmask structures in memory semiconductor devices.

In semiconductor chips, the devices fabricated in or on a semiconductor substrate are connected with a metallic interconnection structure made of metal lines and “vias” which interconnect the metal lines. The metal lines are arranged in horizontal layers, i.e. parallel to the substrate, and separated by layers of dielectrics while vias are disposed vertically in openings in the dielectric to interconnect the layers of metal lines. One important class of semiconductor device is a memory device.

Of memory devices, magnetoresistive random-access memory (MRAM) is an important “new” technology. Although the technology has been in development since the mid-1980s, the improvements in mainstream memory technologies, e.g., in flash RAM and DRAM, have kept MRAM in a niche role. Nonetheless, many believe that MRAM has potential to become the dominant type of memory in the market. Data in MRAM is stored by magnetic storage elements. The elements are formed from ferromagnetic plates typically comprised of layers of magnetic tunnel junction (MTJ) material formed into pillars.

One of the problems with MRAM is that the thick metal hardmask used for patterning memory device pillars creates sufficient stress to cause the semiconductor wafer to bow in a direction which results in misalignment of the memory pillar containing the memory element with respect to a bottom electrode which connects the memory element with the rest of the integrated circuit.

Thus, preventing misalignment in an improved interconnection structure is desirable. The present disclosure presents a method and structure to address the above described problem.

### BRIEF SUMMARY

According to this disclosure, a structure and a method for fabricating a memory device for an integrated circuit device. A metallic hardmask is formed having a selected stress designed to create a selected amount of positive wafer bow. In preferred embodiments, metallic hardmask is disposed on a memory pillar layer over a wafer substrate. A set of memory pillars using the metal hardmask. Because of the positive wafer bow, the patterned set of memory pillars at both the edges and the central portion of the wafer substrate are aligned with a respective contact for a memory device. A positive wafer bow is defined as a bowed wafer substrate where a central portion of a patterned side of the wafer substrate is lower than the edges of the wafer substrate.

The foregoing has outlined some of the more pertinent features of the disclosed subject matter. These features should be construed to be merely illustrative. Many other beneficial results can be attained by applying the disclosed subject matter in a different manner or by modifying the invention as will be described.

### BRIEF DESCRIPTION OF THE DRAWINGS

For a more complete understanding of the present invention and the advantages thereof, reference is now made to the following descriptions taken in conjunction with the accompanying drawings which are not necessarily drawing to scale, and in which:

FIG. 1 is a cross-sectional diagram depicting a prior art contact structure for a Magnetoresistive random-access memory (MRAM) device illustrating the problem experienced by the prior art;

FIG. 2 is a cross-sectional diagram depicting a contact structure for a Magnetoresistive random-access memory (MRAM) device solving the problem experienced by the prior art according to a first embodiment of the invention;

FIG. 3 is a cross-sectional diagram depicting the hardmask structure according to a first embodiment of the invention;

FIG. 4 is a cross-sectional diagram depicting the hardmask structure according to a second embodiment of the invention;

FIG. 5 is a cross-sectional diagram depicting the hardmask structure according to a third embodiment of the invention;

FIG. 6 is a cross-sectional diagram depicting the structure according to a first embodiment of the invention after a bottom electrode contact is deposited;

FIG. 7 is a cross-sectional diagram depicting the structure according to a first embodiment of the invention after a bottom electrode and memory stack are deposited;

FIG. 8 is a cross-sectional diagram depicting the structure according to a first embodiment of the invention after a metal hardmask layer deposition process is performed;

FIG. 9 is a cross-sectional diagram depicting the structure according to a first embodiment of the invention after the memory element is patterned;

FIG. 10 is a cross-sectional diagram depicting the structure according to a first embodiment of the invention after encapsulation of the memory element and etch back of the structure is performed; and

FIG. 11 is a cross-sectional diagram depicting the structure according to a first embodiment of the invention after the top contact layer is formed.

### DETAILED DESCRIPTION OF THE DRAWINGS

At a high level, embodiments of the invention provide a metal hardmask under tensile stress to overcome compressive stresses in other layers of the semiconductor wafer. In preferred embodiments, the hardmask is disposed on top of a bottom electrode contact in a Magnetoresistive random-access memory (MRAM) device. Unlike the prior art metal hardmasks which resulted in a “negative” wafer bow due to a compressive being exerted by the hardmask, in embodiments of the invention, the material for the hardmask is selected to create a tensile stress which creates a “positive” wafer bow. For the purposes of the invention, a “negative” wafer bow is created when the central portion of the patterned side of the wafer is higher than the edges of the wafer. A positive bow is the opposite; the central portion of the patterned side is lower than the edges of the wafer.

An embodiment of this invention can be used to create a nominally a flat wafer, overcoming the compressive stresses in other layers of the semiconductor wafer, but in the inventors’ experience, because of the force exerted by the chuck which holds the wafer during the lithography patterning step, a positive bow will produce the best alignment. In the embodiments described below, this invention emphasizes that a controlled positive bow to the wafer will help in improving alignment of memory elements throughout the wafer. The tensilely stressed metal hardmask layer compensates for other layers, largely underlying layers, of the wafer which exert a compressive stress.

However, too much tensile stress created by the hardmask is not beneficial to alignment. For a 300 mm wafer in preferred embodiments, a maximum positive bow should be approximately 100 microns. However, the maximum positive bow also depends on the overlay margin of the chip design. For example, if overlay margin is greater than 20 nm for a MTJ stack, the maximum positive bow can be larger.

In embodiments of the invention, the hardmask is used to create an MRAM device. In these embodiments, the bottom electrode layer and other layers underneath MRAM pillar as well as the layers which will comprise the MRAM pillar induce certain amount of compressive and tensile stress in the wafer. The hardmask is designed to have a selected amount of stress to compensates for the other layers. In the MRAM embodiments, usually an aggregate tensile stress is needed.

When patterning any material herein, the material to be patterned can be grown or deposited in any known manner and a patterning layer (such as an organic photoresist aka “resist”) can be formed over the material. The patterning layer (resist) can be exposed to some form of light radiation (e.g., patterned exposure, laser exposure) provided in a light exposure pattern, and then the resist is developed using a chemical agent. This process changes the characteristic of the portion of the resist that was exposed to the light. Then one portion of the resist can be rinsed off, leaving the other portion of the resist to protect the material to be patterned. A material removal process is then performed (e.g., plasma etching) to remove the unprotected portions of the material to be patterned. The resist is subsequently removed to leave the underlying material patterned according to the light exposure pattern.

Aspects of the present invention will be described in terms of a given illustrative embodiment; however, other embodiments which include other structures, substrates, materials and process features and steps can be varied within the scope of aspects of the present invention.

When an element such as a layer, region or substrate is referred to as being “on” or “over” another element, it can be directly on the other element or intervening elements can also be present. In contrast, when an element is referred to as being “directly on”, “directly over” or “contacting” another element, there are no intervening elements present. When an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Those skilled in the art will appreciate that descriptions in the specification to an embodiment means that a particular feature, structure, characteristic, is included in at least one embodiment, but not all embodiments. The phrase “in an embodiment”, as well any other variations, appearing in various places throughout the specification are not necessarily all referring to the same embodiment.

Embodiments will be explained below with reference to the accompanying drawings.

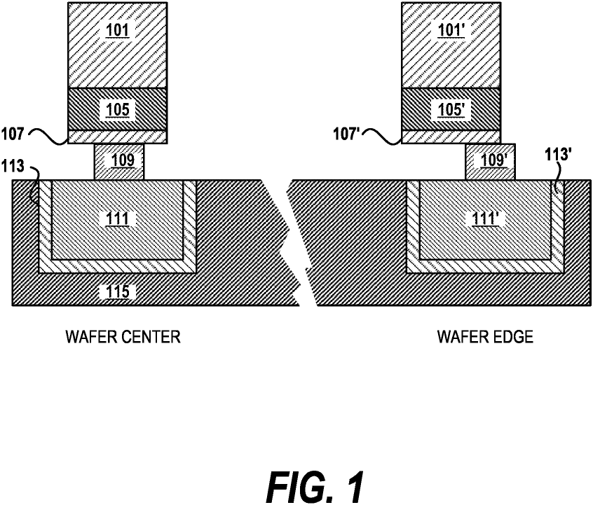

FIG. 1 is a cross-sectional diagram depicting a prior art contact structure for a Magnetoresistive random-access memory (MRAM) device illustrating the problem experienced by the prior art. At a high level, the negative wafer curvature caused by the prior art thick metal hardmask causes misalignment of the magnetic tunnel junction (MTJ) stack with respect to the bottom electrode contact. As shown, at the wafer center (shown in the left of the drawing), the MTJ stack, comprised of hardmask element 101, MTJ/memory element 105 and electrode layer 107 is aligned with respect to the bottom electrode contact 109. The bottom electrode contact 109 is in turn aligned to the underlying circuitry, in the illustrated case, a metal line 111 encased by barrier layer 113 to protect dielectric layer 115. However, due to the wafer curvature caused by the prior art metal hardmask, at the wafer edge, the MTJ stack is misaligned. As shown in the right of the drawing, the MTJ stack at the wafer edge, comprised of hardmask element 101′, MTJ/memory element 105′ and electrode layer 107′, is misaligned with respect to the bottom electrode contact 109′. Since the thick metal hardmask is not yet present, and inducing curvature, at the time the bottom electrode contact 109′ is formed, it is aligned to the underlying circuitry (metal line 111′ encased by barrier layer 113′ to protect dielectric layer 115′).

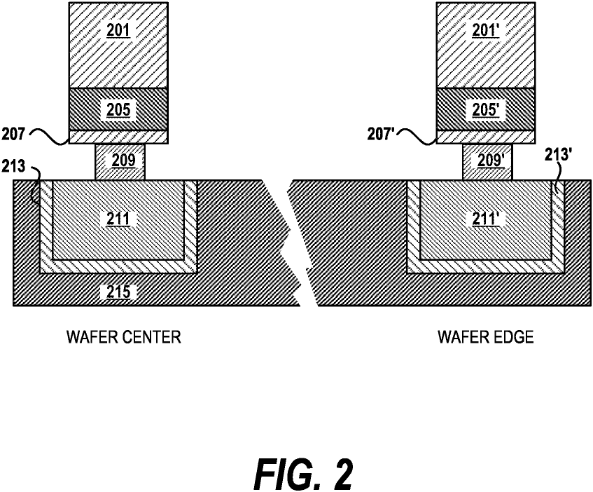

FIG. 2 is a cross-sectional diagram depicting a contact structure for an MRAM device solving the problem experienced by the prior art according to a first embodiment of the invention. As compared to the prior art, the wafer curvature caused by the thick metal hardmask of the present invention is positive. Thus, misalignment of the magnetic tunnel junction (MTJ) stack with respect to the bottom electrode contact is avoided. As shown, both at the wafer center (shown in the left of the drawing) and the wafer edge the MTJ stack is aligned to the bottom electrode contact. Similar to the previous drawing, the wafer center MTJ stack is comprised of hardmask 201, MTJ/memory element 205 and electrode layer 207 is aligned with respect to the bottom electrode contact 209. The bottom electrode contact 209 is aligned to the metal line 211 encased by barrier layer 213 in dielectric layer 215.

Further, at the wafer edge, the MTJ stack (shown in the right of the drawing) is also aligned to the bottom electrode contact. At the right side, the MTJ stack is comprised of hardmask 201′, MTJ/memory element 205′ and electrode layer 207′. The bottom electrode contact 209′ is aligned to metal line 211′ which is encased by barrier layer 213′ in the dielectric layer. While this illustrative example shows an MRAM device, in other embodiments of the invention, other types of random access memory (RAM) devices which have patterned pillars such as resistive RAM (ReRAM) and phase-change RAM (PCRAM) are used.

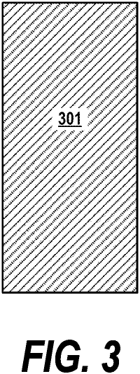

FIG. 3 is a cross-sectional diagram depicting the hardmask structure according to a first embodiment of the invention. In this embodiment, a single layer of tensilely stressed metal is deposited as the hardmask 301. While the hardmask is usually described as a “metal”, metallic compounds, i.e., the nitrides, oxides or carbides of metals are also suitable and would be considered as alternatives. For the purposes of the invention, a “metallic hardmask” includes both a metal or a metal nitride, oxide or carbide. Examples of materials that can be used to form the metal hardmask include, but are not limited to, Nb, NbN, W, WN, Ta, TaN, Ti, TiN, Ru, Mo, Cr, V, Pd, Pt, Rh, Sc, Al, Cu, and other high melting point metals or conductive nitrides, oxides or carbides. While some of these materials have been used in prior art hardmasks, the hardmasks of the present invention differ in that they have a net tensile stress which is applied by the hardmask on the wafer. The selection of the desired amount of tensile stress can be accomplished, as is discussed in greater detail below in a number of ways. For example, by increasing the deposition temperature in the hardmask deposition process, a post treatment after deposition using X-ray, ion or electron bean radiation or doping the hardmask material. Depending on the process conditions used to deposit the hardmask 301, the stress of the hardmask on the wafer can be adjusted to be either tensile or compressive in nature.

The exemplary embodiments include a hardmask that creates an aggregate tensile stress as the invention has been developed with a MRAM application and the underlying layer together with the prior art hardmask created a negative bow in the wafer. However, the goal in the invention is to create a slight positive bow in the wafer. In other embodiments of the invention, where the underlying layers create a tensile stress that creates too much of a positive bow in the wafer, the invention adds a compressively stressed hardmask so that the positive bow in the wafer is optimized.

Because tensile stresses are not easily measured, but wafer bow can be measured easily, the inventors have found that an empirical approach, adjusting the aggregate tensile stress as needed to create a desired amount of positive wafer bow in a set of experiments has yielded the best results. As is mentioned elsewhere in the specification, the inventors have found that a slight positive bow is optimal for alignment of the memory stack to underlying layers. A slight positive bow helps because the chucking forces in the lithography tool induce a slight negative bow on wafer. If the incoming wafer bow is positive, the wafer becomes flat at the lithography tool after chucking. In embodiments of the invention, the desired amount of positive bow is dependent on the chucking forces induced by the lithography tools.

As will be discussed below, there are many combinations of materials and their relative thicknesses which are used in embodiments of the invention. Different material combinations will require different thickness combinations to achieve a net positive bow. Although new deposition techniques developed in the future can be used in embodiments of the invention, existing deposition techniques are used in embodiments of the invention. It is known which materials cause respective tensile and compressive stresses under which respective process conditions. The particular material thickness combination, deposition conditions and post deposition treatments are used to adjusting the aggregate stress of the hardmask to create a positive bow of the wafer.

As will be understood by those skilled in the art, a minimum or maximum thickness for the hardmask is dependent on the underlying layers and the temporary layers which are required for creating the underlying layers to create the desired positive wafer bow Nonetheless, typically the total hardmask thickness ranges from 20 -200 nm in embodiments of the invention. In general, better alignment has been observed with positive wafer bows less than one hundred microns for 300 mm wafers. In some case, the positive wafer bow can be larger if the alignment margin is relatively greater between features for a particular design.

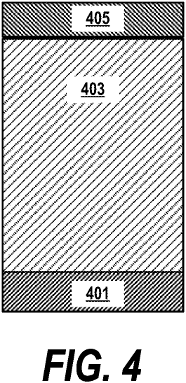

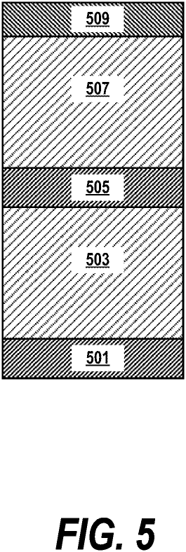

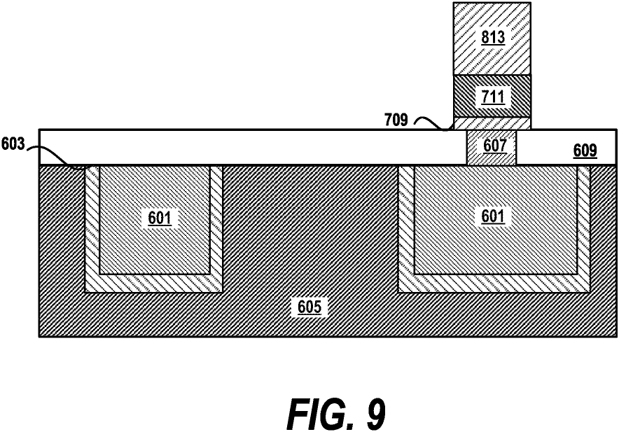

This drawing, as well as the following FIGS. 4 and 5 show a respective element of the patterned hardmask as patterned with lithography. Over the wafer, many similar hardmask elements are patterned to create respective memory cells in the integrated circuit devices. One known lithography process is discussed below in connection with FIG. 9.

FIG. 4 is a cross-sectional diagram depicting the hardmask structure according to a second embodiment of the invention. In this embodiment, multiple layers of hardmask material are deposited. Specifically, compressively stressed layers 401 and 405 sandwich tensively stressed layer 403. This embodiment illustrates a case that the total desired tensile stress is not accomplished with a single layer of material, given the additional requirements of the hardmask to have a given thickness for the patterning of the memory element. In this embodiment, compressively stressed layers 401 and 405 are added to reduce the composite stress closer to the desired positive bow curvature for the wafer. In specific embodiments, the composite stress is selected to be neutral or slightly tensile. While many materials can be used in embodiments of the invention, in some preferred embodiments, Ta and Ti or their nitrides (TiN, TaN) are used hardmask layers to produce a desired amount of net tensile stress for the composite hardmask.

FIG. 5 is a cross-sectional diagram depicting the hardmask structure according to a third embodiment of the invention. This embodiment illustrates that the multiple layers of hardmask material can be deposited so that the compressive and tensile stresses are more evenly distributed throughout the hardmask. Specifically, compressively stressed layers 501, 505 and 509 sandwich tensively stressed layers 503 and 507. In specific embodiments, the composite stress is selected to be neutral or slightly tensile. While this embodiment shows five layers, any number of multiple compressive and tensile layers can comprise the hardmask layer. In alternative embodiments, the compressively stressed layers could be reversed, i.e., so that there are three tensilely stressed layers and two compressively stressed layers. Those skilled in the art will understand that the thicknesses and number of respectively tensilely and compressively stressed layers will differ in different embodiments of the invention.

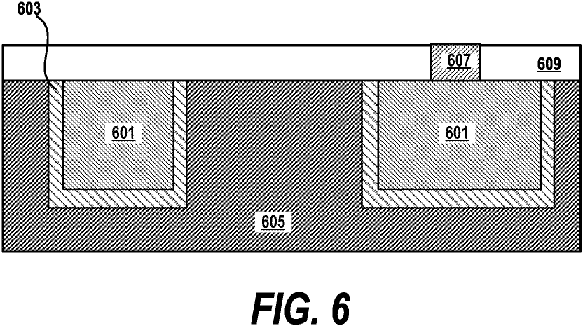

FIG. 6 is a cross-sectional diagram depicting the structure according to a first embodiment of the invention after a bottom electrode contact is deposited. The device is shown in an intermediate state. In the drawing, the metal lines 601, or other metal interconnect such as a via, which connect to the MRAM device and other devices in the integrated circuit are formed in a substrate layer 605. A bottom electrode contact 607 is shown aligned to and in electrical contact with the right metal line 601. The lack of a bottom electrode contact over the left metal line 601 is intended to portray a common case where some of metal lines connect the memory devices to other elements of the integrated circuit while other metal lines are used for other devices (other devices not shown).

In preferred embodiments, the substrate layer 605 comprises a dielectric such silicon dioxide (SiO2). Other embodiments use silicon nitride (SiN), silicon carbide (SiC), or low-k dielectric materials as the substrate layer 605. One skilled in the art will appreciate that many device layers will lie below substrate layer 605 in a typical integrated circuit but are omitted for clarity and ease of illustration. The metal lines 601 are fabricated from a conductive material, for example, a metal such as W, Cu, Al, or alloys thereof. A diffusion barrier layer 603, for example TaN or TiN, is used to prevent diffusion of the metal, e.g., Cu, into the dielectric. The diffusion barrier is optional as some metals (e.g., Co, Ru) do not diffuse into the dielectric. Although only two metal lines 601 and a single bottom electrode contact 607 are shown for ease in illustration, the device structure is usually more complicated and includes a plurality of metal lines and MRAM devices. In embodiments of the invention, a dielectric capping layer 609 is deposited and planarized around bottom electrode contact 607. This dielectric capping layer 609 is SiC, SiN, silicon carbon nitride (SiCN), or hydrogen doped SiCN in respective embodiments. In preferred embodiments, the dielectric capping layer 609 is a different dielectric than that used in substrate layer 605.

In addition to the MRAM devices, the substrate comprises a number of dielectric layers and semiconductor material layers arranged to provide other microelectronic devices including other semiconductor devices, such as field effect transistors (FETs), fin type field effect transistors (FinFETs), bipolar junction transistors (BJT) and combinations thereof. Examples of materials that can be used to form the bottom electrode contact 607 include, but are not limited to, Nb, NbN, W, WN, Ta, TaN, Ti, TiN, Cu, Al, Ru, Mo, Cr, V, Pd, Pt, Rh, Sc, Al and other high melting point materials or conductive nitrides.

The layers in FIG. 6 are formed in conventional processes in some embodiments of the invention. A patterned etch of the dielectric substrate layer 605 can provide the metal line pattern. The dielectric may be selected from the group of, but are not limited to, SiO2, low-k dielectric materials, ULK dielectric material and TEOS. Metal lines 601, barrier layers 603 and bottom electrode contact 607 can be formed in conventional deposition processes such as an atomic layer deposition (ALD), chemical vapor deposition (CVD), plasma enhanced chemical vapor deposition (PECVD), electroless plating. After filling the metal line pattern with the barrier layer and metal line conductor, a planarization process such as chemical mechanical polishing (CMP) is used to remove excess metal from field areas in some embodiments. Next, the bottom electrode contact 607 is formed using conventional damascene process or subtractive metal patterning and dielectric fill process. The bottom electrode contact 607 is encapsulated by dielectric capping layer 609. In preferred embodiments, the capping layer 609 is comprised of a dielectric such as SiN, SiC, SiCN, or hydrogen doped SiCN and is deposited by known deposition techniques.

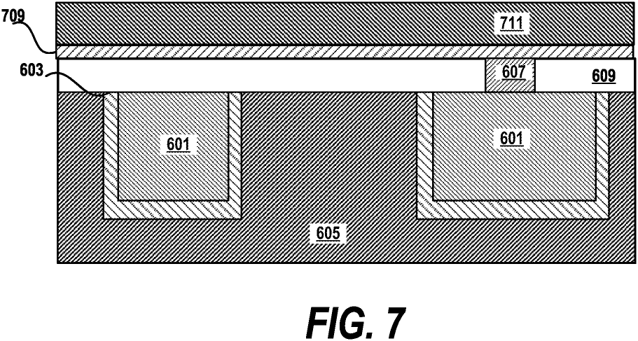

FIG. 7 is a cross-sectional diagram depicting the structure according to a first embodiment of the invention after a bottom electrode and memory stack are deposited. The bottom electrode layer 709 is typically a conductive material such as Nb, NbN, W, WN, Ta, TaN, Ti, TiN, Cu, Al, Ru, Mo, Cr, V, Pd, Pt, Rh, Sc, Al, or alloys thereof. The memory layer 711 is typically a stack of layers or memory stack. For example, the memory stack may be in an MRAM device. Data in an MRAM device is stored as a magnetic polarization or magnetization in magnetic storage elements formed in the magnetic tunnel junction (MTJ) stack. Although depicted as a single memory layer 711, memory stacks in MRAM elements are usually formed from two ferromagnetic plates, each of which can hold a magnetic polarization, separated by a thin insulating layer called the tunnel barrier layer. In embodiments of the invention, one of the two plates is a permanent magnet set to a particular magnetic polarity, the reference plate; the other plate’s magnetization can be changed to match that of an external field to store memory, the free plate. This arrangement is known as a magnetic tunnel junction. Each MRAM cell device stores an MRAM bit. A complete MRAM memory device is built from a grid of such “cells”, though only one cell is depicted in FIGS. 6-11

In the example embodiment, memory layer 711 is an MTJ stack in a laminate structure, e.g., comprised of two ferromagnetic plates separated by a non-magnetic material, such as a nonmagnetic metal or insulator, is formed. A known MTJ structure uses cobalt (Co), iron (Fe), boron (B), nickel (Ni), iridium (Ir), platinum (Pt), palladium (Pd), or any combination thereof as the reference layer. MgO (among other materials) is used as the tunnel barrier layer and CoFeB as the free layer. However, other MTJ structures are known to the art and could be used in embodiments of the invention.

As is mentioned elsewhere in the specification, in other embodiments of the invention, other types of memory pillars for other memory devices such as such as resistive RAM (ReRAM) and phase-change RAM (PCRAM) are used. The invention has wide applicability for any memory device in which memory pillars are fabricated using a hard mask for patterning

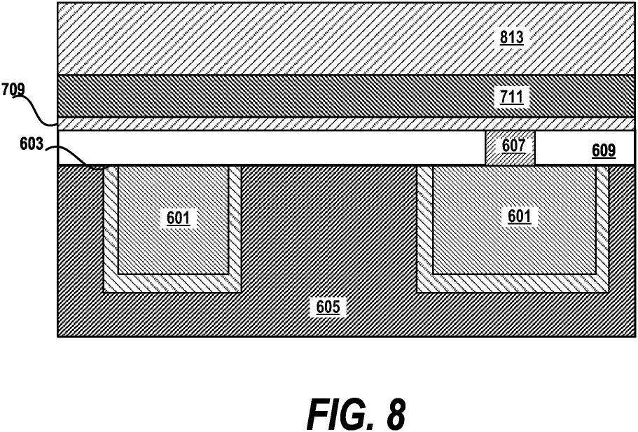

FIG. 8 is a cross-sectional diagram depicting the structure according to a first embodiment of the invention after a metal hardmask layer deposition process is performed. While in some embodiments, the hardmask is a metal, other embodiments use conductive metal nitrides, metal oxides or metal carbides. Embodiments of the invention select respective hardmask materials based on the amount of stress, e.g., tensile, to be created by the hardmask to compensate for the stress created by underlying layers as well as create the desired positive bow for the particular lithography step and the thickness of the hardmask needed for the etch steps which create the features under the hardmask.

Hardmask 813 is depicted as the single tensilely stressed layer of FIG. 3, however, as is depicted in FIGS. 4 and 5, multiple layers of hardmask material can be deposited as part of the entire hardmask layer. As is mentioned above, the formation of tensilely stressed layers can be accomplished in a variety of ways, e.g., by increasing or adjusting the deposition temperature in the deposition process, a simultaneous deposition and radiation treatment using X-ray, ion or electron bean radiation, a post treatment using these radiations or doping the hardmask material. In embodiments of the invention, the hardmask layer thickness can range from 20 to 300 nm with a more preferred range of 50 to 200 nm. In memory stack embodiments of the invention, the hardmask thickness is determined in part by the total pillar height requirement for the memory pillar. For example, when the memory devices are embedded in the “back-end of the line” (BEOL) structures, the thickness is dependent on the heights and widths of the critical features. That is, 55 nm, 28 nm, 22 nm, 14 nm technologies will require different hardmask thicknesses. In addition, the hardmask needs to be tall enough to contact the top electrode contact while keeping safe distance of the contact region from MTJ device. As discussed above, examples of materials that can be used to form the metal hardmask include, but are not limited to, Nb, NbN, W, WN, Ta, TaN, Ti, TiN, Ru, Mo, Cr, V, Pd, Pt, Rh, Sc, Al, Cu, and other high melting point metals or metallic nitrides, carbides or oxides.

For example, by increasing the deposition temperature in a PVD deposition process to 100-500 degrees Centigrade for Ta, TaN, Ti, or TiN the metal or metal nitride film is tensilely stressed rather than compressively stressed. A typical prior art PVD process uses a deposition of less than 100° C. Some embodiments use a combination of PVD deposition temperatures. For example, in the embodiment portrayed in FIG. 4, the first compressively stressed hardmask layer 401 is deposited below 100° C., The tensilely stressed hardmask layer 403 is deposited between 100 - 500° C. Finally, the second compressively stressed hardmask layer 405 is deposited below 100° C. temperature. In alternative embodiments, the boundaries between tensile and compressive layers are continuous, i.e., gradually increasing and decreasing the temperature to create differently stressed layers. Continuous boundaries can be created by gradually adjusting the doping or radiation process conditions at the layer boundaries, rather than abruptly changing process conditions.

In embodiments of the invention, the tensilely and compressively stressed layers can use the same base metal; in other embodiments, the tensilely and compressively stressed layers can use different base metals.

As another example, a simultaneous deposition and radiation treatment using X-ray, ion or electron beam radiation or a post treatment of a deposited layer using these radiations is used to provide tensilely stressed hardmask layers in other embodiments. In some of these embodiments, a W, Ta(N) or Ti(N) layer is deposited in an atomic layer deposition (ALD) or physical vapor deposition (PVD) to a desired thickness. Then, the layer is subjected to radiation treatment to create a tensilely stressed layer. In preferred embodiments the thickness of the hardmask layer is between 10 nm and 100 nm and graduation of the resulted stress is expected. Alternatively, if the tensilely stressed layer is relatively thick, the PVD and radiation processes are simultaneously or concurrently applied to the layer. When an ion radiation treatment is used, a positively charged noble gas ion, e.g., Ar+ or Kr+, is used in embodiments of the invention. Ion radiation treatments of semiconductor layers are well known in the prior art, though not for this particular application.

As yet another example, doping a deposited metal layer such as Fe, Zn, Ti, or other metals can be used to create a tensilely stressed layer. After a conventional deposition process, e.g., PVD or ALD, is used to deposit the metal layer, various dopants such as O, N, Si, C, P and B are used to dope the metal layer in different embodiments to provide the desired tensile stress.

FIG. 9 is a cross-sectional diagram depicting the structure according to a first embodiment of the invention after the memory element is patterned. The patterning can be accomplished through conventional lithographic processes. For example, lithographic layers (not shown) including a mask and a lithography stack are formed on the hardmask 813. The lithographic stack can include a resist layer, an organic planarization layer (OPL) and an antireflective coating (ARC) layer. Once the lithographic stack has been patterned, the hardmask 813, memory layer 711 and the bottom electrode layer 709 are etched to provide the memory pillars. Other lithography layers are known to the art and can be used in other embodiments of the invention. As has been discussed previously, only one memory pillar/element is depicted for ease in illustration, though in a typical memory device, a plurality of memory elements is provided.

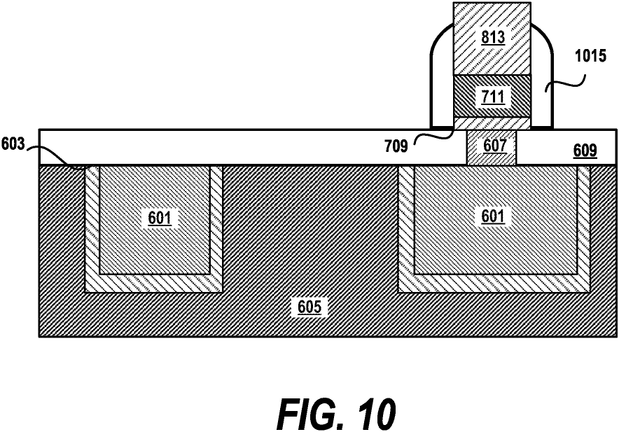

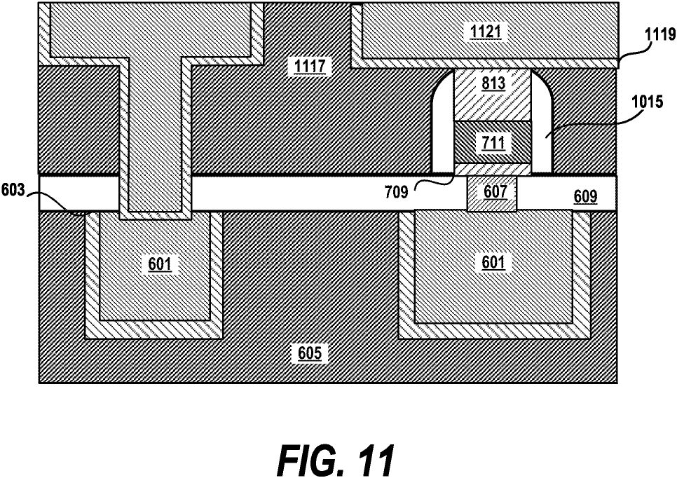

FIG. 10 is a cross-sectional diagram depicting the structure according to a first embodiment of the invention after encapsulation of the memory element and etch back of the structure is performed. The encapsulation layer 1015 is preferably an insulator such as SiN, SiCN SiNO or SiC and surrounds the MTJ layer 711 as well as the hardmask 813 and bottom electrode layer 709. The function of the encapsulation layer 1015 is to prevent oxygen or moisture diffusion from an interlayer dielectric (ILD) layer 1117 (shown in FIG. 11) to the MTJ layer 711. A chemical vapor deposition (CVD), a plasma enhanced chemical vapor deposition (PECVD), a physical vapor deposition (PVD) or an atomic layer deposition (ALD) are used deposit the encapsulation layer in different embodiments of the invention. Typically, the encapsulation layer 1015 has a thickness from 1 nm to 800 nm with a thickness from 5 nm to 500 nm being more preferred in respective embodiments.

FIG. 11 is a cross-sectional diagram depicting the structure according to a first embodiment of the invention after the top contact layer is formed over an ILD layer and the encapsulated memory unit. Examples of materials that can be used to form the top contact 1121 include, but are not limited to, copper (Cu), cobalt (Co), TaN/Ta, ruthenium (Ru), and/or other BEOL conductive materials or metals. The top contact 1121 can include the same material as, or a different material from, the lower metal lines 601. A diffusion barrier 1119, for example TaN or TiN, is used in some embodiments to prevent diffusion of the top contact 1121 metal, e.g., Cu, into the dielectric 1117 Examples of materials that can be used to form the ILD layer 1117 include, but are not limited to, SiO2, low-k dielectric materials, ULK dielectric material and TEOS.

As is known to the art, the structure is followed by additional processing to fabricate contacts for structures which attach the chip to a packaging substrate so that the chip can be incorporated into a computing device. After completing the integrated circuits in the wafer, the wafer is diced and the individual chips are placed on their respective substrates.

The resulting structure can be included within integrated circuit chips, which can be distributed by the fabricator in wafer form (that is, as a single wafer that has multiple chips), as a bare die, or in a packaged form. In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Embodiments of the invention provide advantages over the prior art by providing good alignment of the memory pillars to underlying elements of the memory device. By creating a tensilely stressed metal hardmask layer as slight positive bow to the wafer is created. The tensile stress is tailored to the technology parameters used in the memory device such as the thicknesses, dimension and stresses in other layers of the wafer as well as the force exerted by the wafer holding chuck.

While only a limited number of features are illustrated in the drawings, those ordinarily skilled in the art would understand that many different types of features could be simultaneously formed with the embodiments herein and the drawings are intended to show simultaneous formation of multiple different types of features. However, the drawings have been simplified to only show a limited number of features for clarity and to allow the reader to more easily recognize the different features illustrated. This is not intended to limit the invention because, as would be understood by those ordinarily skilled in the art, the invention is applicable to structures that include many of each type of feature shown in the drawings.

While the above describes a particular order of operations performed by certain embodiments of the invention, it should be understood that such order is exemplary, as alternative embodiments may perform the operations in a different order, combine certain operations, overlap certain operations, or the like. References in the specification to a given embodiment indicate that the embodiment described may include a particular feature, structure, or characteristic, but every embodiment may not necessarily include the particular feature, structure, or characteristic.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having described our invention, what we now claim is as follows:

1. A method for fabricating a memory device for an integrated circuit device comprising:
forming a metallic hardmask on a memory pillar layer over a wafer substrate, the metallic hardmask having a selected stress designed to create a selected positive wafer bow;
patterning a set of memory pillars using the metal hardmask;
wherein a positive wafer bow is defined as a central portion of a patterned side of the wafer substrate is lower than edges of the wafer substrate and the selected positive wafer bow creates memory pillars at both the edges and the central portion of the wafer substrate aligned with respective underlying elements of a memory device.

2. The method as recited in claim 1, wherein the metallic hardmask has a net tensile stress and is a single layer of tensilely stressed metallic material.

3. The method as recited in claim 1, wherein the metallic hardmask has a net tensile stress and comprises a plurality of metallic layers of alternating tensilely stressed metallic materials and compressively stressed metallic materials.

4. The method as recited in claim 2, wherein the single layer of tensilely stressed metallic material is TiN.

5. The method as recited in claim 3, wherein the plurality of metal layers comprises a tensilely stressed metallic layer of TiN and a compressively stressed metal layer of TaN.

6. The method as recited in claim 1, wherein a net tensile stress for the metallic hardmask is selected to create the positive wafer bow.

7. The method as recited in claim 6, further comprising:
forming a bottom electrode layer over a bottom contact;
as part of the memory pillar, forming a magnetic tunnel junction (MTJ) layer over the bottom electrode layer; and
wherein the MTJ layer and the bottom electrode layer are patterned using the metal hardmask.

8. The method as recited in claim 3, wherein layer boundaries between tensile and compressive layers are continuous, by gradually changing process conditions at the layer boundaries.

9. The method as recited in claim 1, the selected stress of the metallic hardmask is achieved by one or more processes selected from the group of adjusting a deposition temperature of the metallic hardmask, a radiation treatment of the metallic hardmask or doping the metallic hardmask.

10. The method as recited in claim 9, wherein the radiation treatment is selected from the group of X-ray, ion and electron bean radiation.

11. The method as recited in claim 1, wherein the selected amount of positive bow is selected according to a chucking force induced by a lithography tool used when patterning the set of memory pillars.

12. A structure in an integrated circuit device comprising:
a set of metallic hardmask elements each having a net tensile stress for a memory device in the integrated circuit device;
memory pillars under each of the metallic hardmask elements; and
wherein memory pillars at both an edge and a center of a wafer are aligned with a respective bottom contact for the memory device in the integrated circuit device.

13. The structure as recited in claim 12, wherein the metallic hardmask has a single layer of tensilely stressed metallic material.

14. The structure as recited in claim 12, wherein the metallic hardmask has a plurality of metal layers of alternating a tensilely stressed metallic material and a compressively stressed metallic material.

15. The structure as recited in claim 12, further comprising:
a substrate layer comprising a dielectric and a set of metal interconnects which connects respective memory devices to other devices in the integrated circuit device;
where each of the bottom electrode contacts is aligned to and in electrical contact with a respective metal interconnect; and
a planarized capping layer is disposed around the bottom electrode contacts.

16. The structure as recited in claim 12, further comprising an encapsulation layer surrounding each memory pillar and metallic hardmask element.

17. The structure as recited in claim 13, wherein the single layer of tensilely stressed metallic material is TiN.

18. The structure as recited in claim 14, wherein the plurality of metal layers comprises a tensilely stressed metallic layer of TiN and a compressively stressed metal layer of TaN.
